(19) United States
(12) Patent Application Publication
(10) Pub. No.: US 2025/0174592 A1
(43) Pub. Date: May 29, 2025

(54) Electronic device and method for manufacturing the same

(71) Applicant: InnoLux Corporation, Miao-Li County (TW)

(72) Inventor: Ker-Yih KAO, Miao-Li County (TW)

(21) Appl. No.: 18/938,496

(22) Filed: Nov. 6, 2024

Related U.S. Application Data
(60) Provisional application No. 63/602,932, filed on Nov. 27, 2023.

(30) Foreign Application Priority Data
Jun. 25, 2024 (CN) 202410826878.4

(51) Int. Cl. H01L 23/00; H01L 23/31

(52) U.S. Cl. CPC H01L 24/20; H01L 24/19; H01L 23/3107; H01L 2224/19; H01L 2224/2101; H01L 2224/214

(57) ABSTRACT

An electronic device and a manufacturing method thereof are provided. The electronic device includes: an electronic unit including a semiconductor structure and a first crack stopper layer disposed on a first side of the semiconductor structure; a second crack stopper layer disposed on a second side of the semiconductor structure, wherein the first side is opposite to the second side; and a first insulating layer surrounding the electronic unit, wherein a Young's modulus of the first crack stopper layer is less than a Young's modulus of the second crack stopper layer.

### CROSS-REFERENCE TO RELATED APPLICATIONS

This application claims the benefits of the Chinese Patent Application Serial Number 202410826878.4, filed on Jun. 25, 2024, the subject matter of which is incorporated herein by reference.

This application claims the benefit of filing date of U.S. Provisional Application Ser. No. 63/602,932, filed Nov. 27, 2023 under 35 USC § 119(e)(1).

### BACKGROUND

### Field

The present disclosure provides an electronic device and a method for manufacturing the same. More specifically, the present disclosure provides an electronic device comprising a crack stopper layer and a method for manufacturing the same.

### Description of Related Art

With the advancement of electronic device technology, most of today's electronic products are pursuing the pursuit of being light, thin, small, or developing in the direction of high integration. That is, a single electronic device can have multiple functions, and electronic products with more functions are accompanied by the requirements of a larger number of chips, and the integration density must continue to increase.

Generally, electronic devices can undergo grinding steps to thin the wafer or improve the flatness of the wafer during the manufacturing process. However, with the requirement for thinning, it is easy to cause damage or even cracking of the wafer during the thinning step or subsequent processes.

Therefore, it is desirable to provide an electronic device and a method for manufacturing the same to improve the conventional defects.

### SUMMARY

The present disclosure provides an electronic device, which comprises: an electronic unit comprising a semiconductor structure and a first crack stopper layer disposed on a first side of the semiconductor structure; a second crack stopper layer disposed on a second side of the semiconductor structure, wherein the first side is opposite to the second side; and a first insulating layer surrounding the electronic unit, wherein a Young's modulus of the first crack stopper layer is less than a Young's modulus of the second crack stopper layer.

The present disclosure further provides a method for manufacturing an electronic device, comprising the following steps: providing an electronic unit and a second crack stopper layer on the first carrier, wherein the electronic unit comprises a semiconductor structure and a first crack stopper layer disposed on a first side of the semiconductor structure, the second crack stopper layer is disposed on a second side of the semiconductor structure, and the first side is opposite to the second side; disposing a first insulating layer on the first carrier, the electronic unit and the second crack stopper layer so that the first insulating layer surrounds the electronic unit to form a first package structure; turning over the first package structure and disposing the first package structure after turning on a second carrier; patterning the first insulating layer to form a through via; disposing a circuit structure and a second insulating layer on the first package structure to form a second package structure; turning over the second package structure and disposing the second package structure after turning on a third carrier; grinding the first insulating layer and a part of the second crack stopper layer to expose a part of the electronic unit; disposing a metal layer on the electronic unit and the first insulating layer; and disposing a third insulating layer on the first insulating layer, wherein the third insulating layer surrounds the metal layer, wherein a Young's modulus of the first crack stopper layer is less than a Young's modulus of the second crack stopper layer.

The present invention further provides another method for manufacturing an electronic device, comprising the following steps: providing an electronic unit on a first carrier, wherein the electronic unit comprises a semiconductor structure and a first crack stopper layer disposed on a first side of the semiconductor structure; disposing a first insulating layer on the first carrier so that the first insulating layer surrounds the electronic unit; disposing a second crack stopper layer on the electronic unit and the first insulating layer to form a first package structure, wherein the second crack stopper layer is disposed on a second side of the semiconductor structure, and the first side is opposite to the second side; disposing a metal layer and a third insulating layer on the first package structure; grinding a part of the metal layer and the third insulating layer to expose a part of the metal layer to form a second package structure; turning over the second package structure and disposing the second package structure after turning on a second carrier; disposing a circuit structure and a second insulating layer on the second package structure after turning; and disposing a conductive material on the circuit structure, wherein a Young's modulus of the first crack stopper layer is less than a Young's modulus of the second crack stopper layer.

Other novel features of the disclosure will become more apparent from the following detailed description when taken in conjunction with the accompanying drawings.

### BRIEF DESCRIPTION OF DRAWINGS

FIG. 1A to FIG. 1E are schematic views showing a method for manufacturing an electronic device according to one embodiment of the present disclosure.

FIG. 2A to FIG. 2E are schematic views showing a method for manufacturing an electronic device according to one embodiment of the present disclosure.

FIG. 3A is a cross-sectional schematic view of an electronic device according to one embodiment of the present disclosure.

FIG. 3B and FIG. 3C respectively are enlarged views of FIG. 3A.

FIG. 4 is a cross-sectional schematic view of an electronic device according to one embodiment of the present disclosure.

FIG. 5 is a cross-sectional schematic view of an electronic device according to one embodiment of the present disclosure.

FIG. 6 is a cross-sectional schematic view of an electronic device according to one embodiment of the present disclosure.

FIG. 7 is a cross-sectional schematic view of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the distance, the length, the width and the thickness may be measured using an optical microscope or using cross-sectional images in an electron microscope, but the present disclosure is not limited thereto. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

In the present disclosure, the definition of roughness judgment can be observed by scanning electron microscope (SEM). On the uneven surface, a distance difference between the peaks and valleys of the surface profile can be observed. Measurements for roughness judgment can include using SEM, transmission electron microscope (TEM), etc. to observe the surface profile at the same appropriate magnification, and compare the profile by taking a sample with a unit length (for example, 10 μm) to obtain the roughness range. Here, “appropriate magnification” means the range that at least 10 peaks of the profile (Rz) of at least one surface can be observed or the average roughness (Ra) of at least one surface under the field of view of this magnification.

It should be noted that the technical solutions provided in different embodiments below can be replaced, combined or mixed with each other to constitute another embodiment without violating the spirit of the present disclosure.

The electronic device of the present disclosure may be, for example, a semiconductor device, and can be applied to any device. The electronic device of the present disclosure may include, for example, a display device, a sensing device, an antenna device, a touch device, a tiled device or other suitable electronic devices; but the present disclosure is not limited thereto. The display device of the present disclosure may be a non-self-luminous display device or a self-luminous display device, such as a liquid crystal display, a cholesteric liquid crystal display, an electro-phoretic display, an organic light emitting diode display or a light emitting diode display; but the present disclosure is not limited thereto. The display device may comprise a light emitting diode, a light conversion layer, other suitable materials or a combination thereof; but the present disclosure is not limited thereto. The light emitting diode may comprise, for example, an organic light emitting diode (OLED), a mini light emitting diode (mini LED), a micro light emitting diode (micro LED) or a quantum dot light emitting diode (quantum dot LED which may include QLED or QDLED); but the present disclosure is not limited thereto. The light conversion layer may comprise wavelength conversion materials and/or filter materials. The light conversion layer may comprise, for example, fluorescence, phosphors, quantum dots (QDs), other suitable materials or a combination thereof; but the present disclosure is not limited thereto. The sensing device may include, for example, a biosensor, a touch sensor, a fingerprint sensor, other suitable sensors or a combination of the above types of sensors. The antenna device may, for example, be a liquid crystal antenna or other types of antenna; but the present disclosure is not limited thereto. The tiled device may, for example, be a tiled display device or a tiled antenna device; but the present disclosure is not limited thereto. The electronic device may comprise an electronic unit, which may comprise a passive component, an active component or a combination thereof, such as a capacitor, a resistor, an inductor, a varactor diode, a variable capacitor, a filter, a diode, a transistor, a sensor, a microelectromechanical system (MEMS), or a chip; but the present disclosure is not limited thereto. It should be noted that the electronic device of the present disclosure may be any combination of the above devices; but the present disclosure is not limited thereto. The method for manufacturing the electronic device in the present disclosure can be applied, for example, in a wafer-level package (WLP) process or a panel-level package (PLP) process, where the wafer-level package or panel-level package process can include, but is not limited to, a chip-first process or a chip-last process. The electronic device of the present disclosure may be applied, for example, in power modules or semiconductor packaging device, but the present disclosure is not limited thereto. The electronic device may comprise a system on a ship (SoC), a system in a package (SiP), an antenna in package (AiP) or any combination of the above devices, but the present disclosure is not limited thereto.

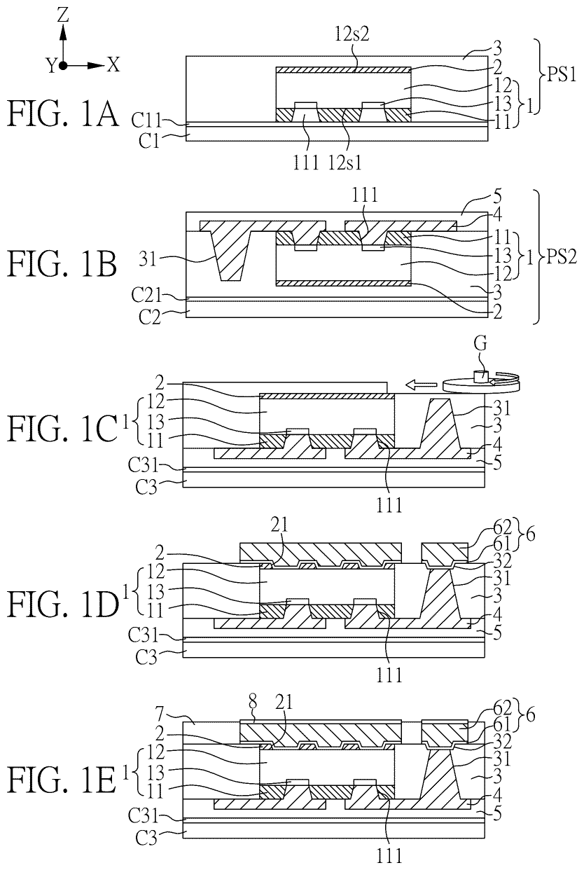

FIG. 1A to FIG. 1E are schematic views showing a method for manufacturing an electronic device according to one embodiment of the present disclosure.

In one embodiment of the present disclosure, the method for manufacturing an electronic device may comprise the following steps. As shown in FIG. 1A, an electronic unit 1 and a second crack stopper layer 2 are provided on the first carrier C1, wherein the electronic unit 1 comprises a semiconductor structure 12 and a first crack stopper layer 11 disposed on a first side 12s1 of the semiconductor structure 12, the second crack stopper layer 2 is disposed on a second side 12s2 of the semiconductor structure 12, and the first side 12s1 is opposite to the second side 12s2. Next, a first insulating layer 3 is disposed on the first carrier C1, the electronic unit 1 and the second crack stopper layer 2 so that the first insulating layer 3 surrounds the electronic unit 1, wherein the electronic unit 1, the second crack stopper layer 2 and the first insulating layer 3 form a first package structure PS1.

In one embodiment of the present disclosure, as shown in FIG. 1A, the electronic unit 1 may comprise a pad 13 which may be electrically connected to the semiconductor structure 12 to output a signal from the electronic unit 1 or input a signal into the electronic unit 1. In one embodiment of the present disclosure, as shown in FIG. 1A, the first crack stopper layer 11 may comprise an opening 111 exposing the pad 13. In one embodiment of the present disclosure, as shown in FIG. 1A, the first insulating layer 3 further surrounds the second crack stopper layer 2. In one embodiment of the present disclosure, as shown in FIG. 1A, an peeling layer C11 may be selectively disposed between the first carrier C1 and the electronic unit 1 to facilitate the subsequent step of separating the first carrier C1 and the electronic unit 1. According to some embodiments, the material of the pad 13 may comprise aluminum, copper or other conductive materials.

In the present disclosure, the first insulating layer 3 and the peeling layer C11 may be respectively disposed by any suitable method, which may include dip coating, spin coating, roller coating, blade coating, spray coating, deposition or a combination thereof; but the present disclosure is not limited thereto. In the present disclosure, the opening 111 of the first crack stopper layer 11 may be formed through, for example, mechanical drilling, laser drilling, lithography or a combination thereof, but the present disclosure is not limited to the above methods.

In the present disclosure, the material of the first carrier C1 may comprise glass, quartz, sapphire, ceramics, plastic, BT substrate, steel plate, other suitable substrate material or a combination thereof; but the present disclosure is not limited thereto. In the present disclosure, the electronic unit 1 may comprise a passive component and an active component, such as a capacitor, a resistor, an inductor, a diode, a transistor, etc.; but the present disclosure is not limited thereto. Diodes may include light emitting diodes or photodiodes. In the present disclosure, the material of the first crack stopper layer 11 may comprise an organic material or an inorganic material. The organic material may comprise polyimide (PI), poly-p-xylylene (also called as parylene), benzocyclobutene (BCB), epoxy, polycarbonate (PC), polyethylene terephthalate (PET), polyethylene naphthalate (PEN), polymer or other suitable organic material; but the present disclosure is not limited thereto. The inorganic material may comprise silicon oxide, silicon nitride, silicon oxynitride or other suitable inorganic material; but the present disclosure is not limited thereto. In the present disclosure, the material of the second crack stopper layer 2 may comprise polymer, epoxy resin, silicon oxide, silicon nitride, metal or other suitable material; but the present disclosure is not limited thereto. In the present disclosure, the Young's modulus of the first crack stopper layer 11 is different from the Young's modulus of the second crack stopper layer 2. In the present disclosure, the Young's modulus of the first crack stopper layer 11 is less than the Young's modulus of the second crack stopper layer 2. For example, the Young's modulus of the first crack stopper layer 11 may be between 5 GPa and 15 GPa, the Young's modulus of the second crack stopper layer 2 may be between 100 GPa and 150 GPa; but the present disclosure is not limited thereto. In the present disclosure, the thermal conductivity of the second crack stopper layer 2 may be greater than the thermal conductivity of the first crack stopper layer 11 to improve the heat dissipation effect of the electronic unit 1. The thermal conductivity of the first crack stopper layer 11 may be, for example, less than 5 Wm⁻¹K⁻¹, and the thermal conductivity of the second crack stopper layer 2 may be, for example, greater than or equal to 5 Wm⁻¹K⁻¹ and less than or equal to 550 Wm⁻¹K⁻¹; but the present disclosure is not limited thereto. The first crack stopper layer 11 and the second crack stopper layer 2 may be used to protect components of the electronic unit 1, to reduce damage to the electronic unit 1 in subsequent processing steps. In the present disclosure, the material of the first insulating layer 3 may comprise an epoxy resin, a polymer, other suitable material or a combination thereof; but the present disclosure is not limited thereto. According to some embodiments, the material of the first insulating layer 3 may be, for example, a molding compound, and may further comprise filling particles. The material of the filling particles may comprise silicon dioxide, other suitable material or a combination thereof; but the present disclosure is not limited thereto. According to some embodiments, along a normal direction Z of the electronic unit 1, the thickness of the first insulating layer 3 may be greater than the thickness of the electronic unit 1, to facilitate reducing the warpage during the manufacturing process of the electronic devices; but the present disclosure is not limited thereto.

Next, as shown in FIG. 1A and FIG. 1B, the first package structure PS1 is turned over and the first package structure PS1 after turning is disposed on the second carrier C2. The first insulating layer 3 is patterned to form a through via 31. Then, a circuit structure 4 and a second insulating layer 5 are respectively disposed on the first package structure PS1 after turning, wherein the electronic unit 1, the second crack stopper layer 2, the first insulating layer 3, the circuit structure 4 and the second insulating layer 5 form a second package structure PS2.

In the present disclosure, the “turning over the first package structure” refers to, for example, flipping the first package structure PS1 180° in the normal direction Z of the electronic unit 1, and at this time, as shown in FIG. 1A and FIG. 1B, the second crack stopper layer 2 will be turned from being disposed above the electronic unit 1 to being disposed below the electronic unit 1, and the first crack stopper layer 11 will be turned from being disposed below the semiconductor structure 12 to being disposed above the semiconductor structure 12.

In one embodiment of the present disclosure, as shown in FIG. 1B, the circuit structure 4 may be disposed in the through via 31 of the first insulating layer 3 and the opening 111 of the first crack stopper layer 11, and the circuit structure 4 may be electrically connected to the semiconductor structure 12 through the pad 13 of the electronic unit 1. In one embodiment of the present disclosure, as shown in FIG. 1B, a peeling layer C21 may be selectively disposed between the second carrier C2 and the second package structure PS2 to facilitate the subsequent step of separating the second carrier C2 and the second package structure PS2.

In one embodiment of the present disclosure, before the step of disposing the first package structure PS1 after turning on the second carrier C2, a step of removing the first carrier C1 may be further performed. In the present disclosure, the first carrier C1 may be removed by applying an external force to the first carrier C1. The “external force” may include physical, chemical or optical external force or stress such as heating, laser, ultraviolet light, mechanical force or a combination thereof; but the present disclosure is not limited thereto.

In the present disclosure, any suitable method may be used for patterning, which may comprise, for example, lithography or etching. The etching may comprise dry etching, wet etching or a combination thereof; but the present disclosure is not limited thereto. In the present disclosure, any suitable method may be used to dispose the circuit structure 4, the suitable method may include electroplating, chemical plating, chemical vapor deposition, physical vapor deposition, atomic layer deposition (ALD), sputtering, lamination, coating or a combination thereof; but the present disclosure is not limited thereto. The “coating” may be, for example, dip coating, spin coating, roller coating, blade coating, spray coating or a combination thereof; but the present disclosure is not limited thereto. In the present disclosure, the method for disposing the second insulating layer 5 may be similar to the method for disposing the first insulating layer 3, and is not described here again.

In the present disclosure, the material of the second carrier C2 may be the same or different from the material of the first carrier C1, and is not described here again. In the present disclosure, the material of the circuit structure 4 may comprise metal, metal oxide, an alloy thereof or a combination thereof, and for example, may comprise gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), aluminum zinc oxide (AZO) or a combination thereof; but the present disclosure is not limited thereto. In the present disclosure, the material of the second insulating layer 5 may comprise glass, polyimide (PI), poly-p-xylylene (also called as parylene), benzocyclobutene (BCB), epoxy, polycarbonate (PC), polyethylene terephthalate (PET), polyethylene naphthalate (PEN), polymer or other suitable material; but the present disclosure is not limited thereto. According to some embodiments, the circuit structure 4 may be, for example, a redistribution layer (RDL), which can be electrically connected to each chip or electronic unit through solder balls or other joint components. The circuit structure 4 may further comprise at least one conductive layer and at least one insulating layer, or the circuit structure 4 may make the circuits redistributed and/or the circuit fan-out area further improved, or different electronic units may be electrically connected through the redistribution structure. Alternatively, the redistribution layer may be used as a substrate that serves as the electrical interface routing between one connection and another connection. The purpose of the redistribution layer is to extend a wire to a wider spacing or to reroute a wire to another wire with a different spacing.

Next, as shown in FIG. 1C and FIG. 1D, the second package structure PS2 is turned over and the second package structure PS2 after turning is disposed on the third carrier C3. Then, the first insulating layer 3 and a part of the second crack stopper layer 2 are ground to expose a part of the electronic unit 1. Then, a metal layer 6 is disposed on the electronic unit 1 and the first insulating layer 3.

In the present disclosure, the “turning over the second package structure” refers to, for example, flipping the second package structure PS2 180° in the normal direction Z of the electronic unit 1, and at this time, as shown in FIG. 1B and FIG. 1C, the second crack stopper layer 2 will be turned from being disposed below the electronic unit 1 to being disposed above the electronic unit 1, the first crack stopper layer 11 will be turned from being disposed above the semiconductor structure 12 to being disposed below the semiconductor structure 12, and the circuit structure 4 and the second insulating layer 5 will be turned from being disposed above the first package structure PS1 (shown in FIG. 1A) to being disposed below the first package structure PS1 (shown in FIG. 1A). According to some embodiments, after forming the first package structure PS1, the metal layer 6 may be disposed on the electronic unit 1 and the first insulating layer 3, and then flipped over, and then the circuit structure 4 is further disposed. In other words, the metal layer 6 and the circuit structure 4 are respectively disposed on opposite sides of electronic unit 1, and the priority order of disposing the metal layer 6 and the circuit structure 4 is not limited.

In one embodiment of the present disclosure, as shown in FIG. 1C, a peeling layer C31 may be selectively disposed between the third carrier C3 and the second package structure PS2, so the peeling layer C31 may facilitate the subsequent step of separating the third carrier C3 and the second package structure PS2. In one embodiment of the present disclosure, as shown in FIG. 1C, a grinder G may be used to grind the first insulating layer 3 and a part of the second crack stopper layer 2, thereby thinning the thickness of the second package structure PS2 and exposing a part of the second crack stopper layer 2. In one embodiment of the present disclosure, before the step of disposing the second package structure PS2 after turning on the third carrier C3, a step of removing the second carrier C2 may be included. Herein, the method for removing the second carrier C2 may be similar to the method for removing the first carrier C1, and is not described here again. In the present disclosure, the thickness of the second crack stopper layer 2 before grinding is greater than or equal to the thickness of the second crack stopper layer 2 after grinding.

In one embodiment of the present disclosure, as shown in FIG. 1D, after the step of grinding the first insulating layer 3 and a part of the second crack stopper layer 2, a step of respectively patterning the first insulating layer 3 and the second crack stopper layer 2 to expose part of the electronic unit 1 and part of the circuit structure 4 disposed in the through via 31 of the first insulating layer 3 may be selectively included. More specifically, the first insulating layer 3 is patterned to form a through via 32 of the first insulating layer 3, and the through via 31 is connected to the through via 32, wherein a part of the circuit structure 4 disposed in the through via 31 of the first insulating layer 3 is exposed from the through via 32. The second crack stopper layer 2 is patterned to form an opening 21 of the second crack stopper layer 2, wherein a part of the electronic unit 1 is exposed from the opening 21. In the present disclosure, any suitable method may be used in the step of patterning the first insulating layer 3 and the second crack stopper layer 2, and the suitable method may be as described above and is not described here again. According to some embodiments, the step of patterning the first insulating layer 3 and the second crack stopper layer 2 may be omitted.

In one embodiment of the present disclosure, even not shown in the figure, a grinder G may be used to grind the first insulating layer 3 and a part of the second crack stopper layer 2 to expose a part of the electronic unit 1 and a part of the circuit structure 4 disposed in the through via 31 of the first insulating layer 3. Therefore, in some embodiments, the step of patterning the first insulating layer 3 to form the through via 32 and/or the step of patterning the second crack stopper layer 2 to form the opening 21 may be selectively omitted.

In one embodiment of the present disclosure, as shown in FIG. 1D, the metal layer 6 may be disposed in the opening 21 of the second crack stopper layer 2 and in the through via 32 of the first insulating layer 3. The metal layer 6 may comprise a first sub-metal layer 61 and a second sub-metal layer 62, and the second sub-metal layer 62 is disposed on the first sub-metal layer 61, wherein a part of the first sub-metal layer 61 may contact the electronic unit 1 through the opening 21 of the second crack stopper layer 2, and a part of the first sub-metal layer 61 may contact and be electrically connected to the circuit structure 4 disposed in the through via 31 of the first insulating layer 3 through the through via 32 of the first insulating layer 3. In the present disclosure, a suitable method may be used to dispose the metal layer 6, and the suitable method may comprise electroplating, chemical plating, chemical vapor deposition, physical vapor deposition, sputtering or a combination thereof; but the present disclosure is not limited thereto. In the present disclosure, the material of the metal layer 6 may comprise gold, silver, copper, titanium, chromium, nickel, cobalt, an alloy thereof or a combination thereof; but the present disclosure is not limited thereto.

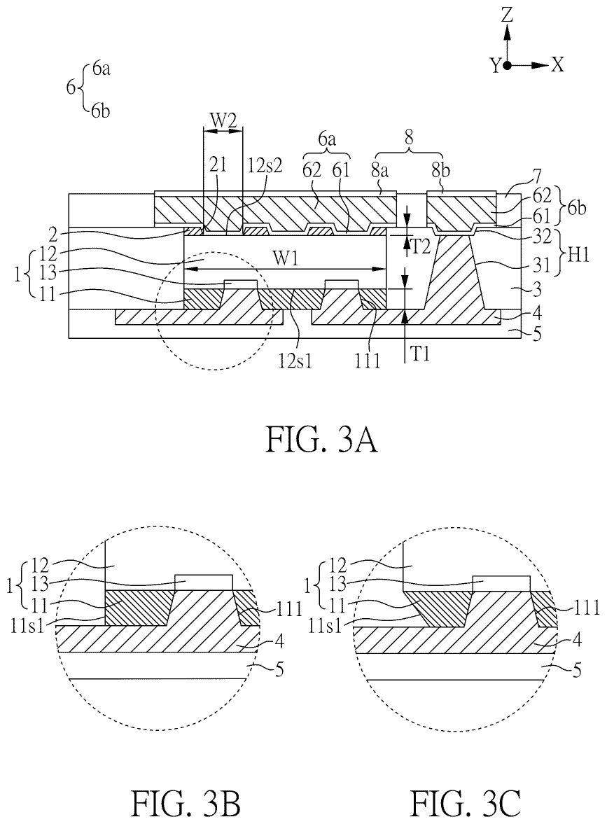

Next, as shown in FIG. 1E, a third insulating layer 7 is disposed on the first insulating layer 3, and the third insulating layer 7 surrounds the metal layer 6. Then, the third carrier C3 is removed to form the electronic device of one embodiment of the present disclosure (for example, as shown in FIG. 3A).

In the present disclosure, the method for disposing the third insulating layer 7 may be similar to the method for disposing the first insulating layer 3, and the method for removing the third carrier C3 may be similar to the method for removing the first carrier C1, so the methods are not described here again. In the present disclosure, the material similar to or different from the material for preparing the first insulating layer 3 may be used to prepare the third insulating layer 7. The material of the third insulating layer 7 is similar to the material of the first insulating layer 3 and is not described here again.

In one embodiment of the present disclosure, as shown in FIG. 1E, before the step of disposing the third insulating layer 7 on the first insulating layer 3, a step of disposing a connecting unit 8 on the metal layer 6 may be included. In the present disclosure, any suitable method may be used to dispose the connecting unit 8, and the suitable method comprises electroplating, chemical plating, chemical vapor deposition, physical vapor deposition, sputtering, coating or a combination thereof; but the present disclosure is not limited thereto. In the present disclosure, the connecting unit 8 may be formed by a material that conduct heat or electricity, and suitable material may comprise gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), aluminum zinc oxide (AZO) or a combination thereof; but the present disclosure is not limited thereto.

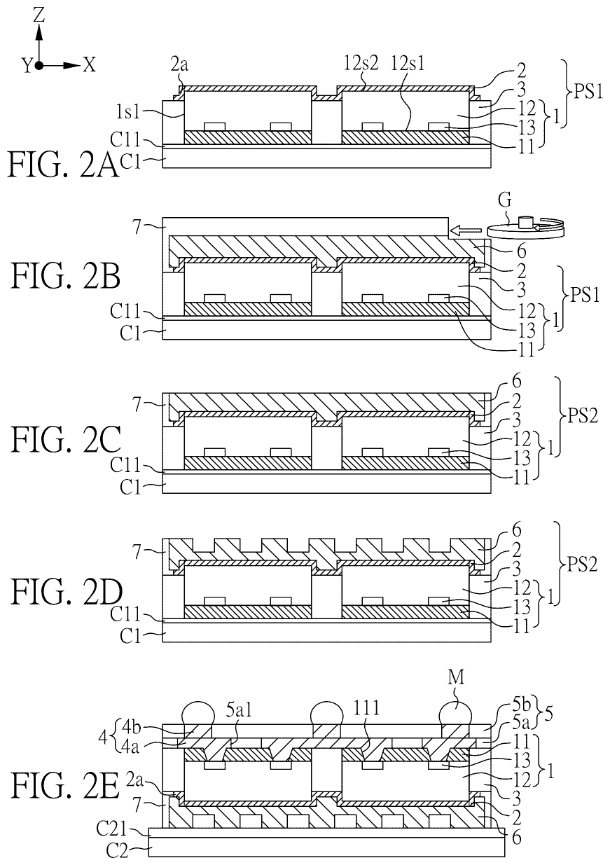

FIG. 2A to FIG. 2E are schematic views showing a method for manufacturing an electronic device according to one embodiment of the present disclosure. The method shown in FIG. 2A to FIG. 2E is similar to that shown in FIG. 1A to FIG. 1E, except for the following differences.

In one embodiment of the present disclosure, the method for manufacturing an electronic device may comprise the following steps. As shown in FIG. 2A, a plurality of electronic units 1 are provided on a first carrier C1, the electronic unit 1 comprises a semiconductor structure 12 and a first crack stopper layer 11, and the first crack stopper layer 11 is disposed on a first side 12s1 of the semiconductor structure 12. Next, a first insulating layer 3 is disposed on the first carrier C1, so that the first insulating layer 3 surrounds the electronic units 1. Then, a second crack stopper layer 2 is disposed on the electronic units 1 and the first insulating layer 3, wherein the second crack stopper layer 2 is disposed on a second side 12s2 of the semiconductor structure 12. The electronic units 1, the second crack stopper layer 2 and the first insulating layer 3 form a first package structure PS1.

In one embodiment of the present disclosure, as shown in FIG. 2A, the electronic unit 1 may comprise a pad 13, and the pad 13 may be electrically connected to the semiconductor structure 12 to output a signal from the electronic unit 1 or input a signal to the electronic unit 1. In one embodiment of the present disclosure, as shown in FIG. 2A, at this time, the first crack stopper layer 11 may not comprise an opening 111 (as shown in FIG. 1A) exposing the pad 13. However, in other embodiments, the first crack stopper layer 11 may comprise the opening 111 shown in FIG. 1A, and the pad 13 is exposed from the opening 111, which is not described here again. In one embodiment of the present disclosure, as shown in FIG. 2A, a peeling layer C11 may be selectively disposed between the first carrier C1 and the electronic unit 1 to facilitate the subsequent step of separating the first carrier C1 and the electronic unit 1. In one embodiment of the present disclosure, as shown in FIG. 2A, a part of the second crack stopper layer 2 may protrude from the electronic unit 1. More specifically, the second crack stopper layer 2 may comprise a protrusion portion 2a, and the protrusion portion 2a and the electronic unit 1 are not overlapped in the top view direction Z of the electronic unit 1 to facilitate the subsequent grinding step. In one embodiment of the present disclosure, as shown in FIG. 2B, a part of the second crack stopper layer 2 may contact a side wall 1s1 of the electronic unit 1. In one embodiment of the present disclosure, the second crack stopper layer 2 may be selectively patterned to form the opening 21 of the second crack stopper layer 2, as shown in FIG. 1D; but the present disclosure is not limited thereto.

In the present disclosure, a suitable method may be used to dispose the second crack stopper layer 2, and the suitable method comprises electroplating, chemical plating, chemical vapor deposition, physical vapor deposition, sputtering, coating or a combination thereof; but the present disclosure is not limited thereto. In the present disclosure, the method for disposing the first insulating layer 3 may be as described above, and is not described here again. In the present disclosure, the material of the first carrier C1, the material of the first crack stopper layer 11, the material of the second crack stopper layer 2, the material of the first insulating layer 3 and the electronic unit 1 may be as described above and are not described here again. In the present disclosure, the Young's modulus of the first crack stopper layer 11 is different from the Young's modulus of the second crack stopper layer 2. In the present disclosure, the Young's modulus of the first crack stopper layer 11 is less than the Young's modulus of the second crack stopper layer 2. For example, the Young's modulus of the first crack stopper layer 11 may be between 5 GPa and 15 GPa, and the Young's modulus of the second crack stopper layer 2 may be between 100 GPa and 150 GPa; but the present disclosure is not limited thereto. In the present disclosure, the thermal conductivity of the second crack stopper layer 2 is greater than the thermal conductivity of the first crack stopper layer 11 to improve the heat dissipation effect of the electronic unit 1. The thermal conductivity of the first crack stopper layer 11 may be, for example, less than 5 Wm⁻¹K⁻¹, the thermal conductivity of the second crack stopper layer 2 may be, for example, greater than or equal to 5 Wm⁻¹K⁻¹ and less than or equal to 500 Wm⁻¹K⁻¹; but the present disclosure is not limited thereto. The first crack stopper layer 11 and the second crack stopper layer 2 may be used to protect components of the electronic unit 1, to reduce damage to the electronic unit 1 in subsequent processing steps.

Next, as shown in FIG. 2B and FIG. 2C, a metal layer 6 and a third insulating layer 7 are disposed on the first package structure PS1, wherein the third insulating layer 7 may cover the metal layer 6 and surround the second crack stopper layer 2. Then, a grinder G is used to grind the third insulating layer 7 and a part of the metal layer 6 to expose a part of the metal layer 6. Herein, the electronic unit 1, the second crack stopper layer 2, the first insulating layer 3, the metal layer 6 after grinding and the third insulating layer 7 after grinding form a second package structure PS2.

In the present disclosure, the methods for disposing the metal layer 6 and the third insulating layer 7 may be as described above, and are not described here again. In addition, the materials of the metal layer 6 and the third insulating layer 7 may be as described above, and are not described here again.

Next, as shown in FIG. 2D, the metal layer 6 is patterned, so that the metal layer 6 has a comb structure which can improve the heat dissipation effect of the electronic unit 1. In one embodiment of the present disclosure, the step of patterning the metal layer 6 shown in FIG. 2D may be selectively omitted and the next step is directly performed. In the present disclosure, any suitable method may be used to proceed the step of patterning the metal layer 6. Suitable method may comprise, for example, lithography and etching, wherein the etching may comprise dry etching, wet etching or a combination thereof; but the present disclosure is not limited thereto.

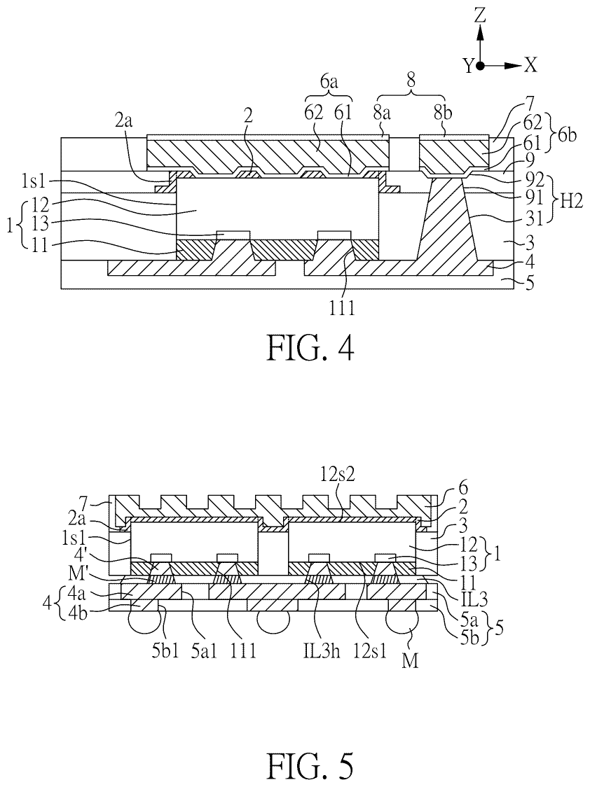

Next, as shown in FIG. 2E, the second package structure PS2 shown in FIG. 2D is turned over, and the second package structure PS2 after turning is disposed on the second carrier C2. Then, the first crack stopper layer 11 is patterned to form an opening 111, and a pad 13 is exposed from the opening 111. Then, a circuit structure 4 is disposed on the second package structure PS2 after turning and in the opening 111 of the first crack stopper layer 11, and a second insulating layer 5 is disposed on the circuit structure 4, wherein the circuit structure 4 may be electrically connected to the semiconductor structure 12 through the pad 13 of the electronic unit 1. Then, a conductive material M is disposed on the circuit structure 4, and the circuit structure 4 may transmit a signal from outside to the electronic unit 1 or transmit a signal from the electronic unit 1 to outside through the conductive material M. Then, the second carrier C2 is removed to form the electronic device of the one embodiment of the present disclosure (for example, as shown in FIG. 5).

In the present disclosure, the “turning over the second package structure” refers to, for example, flipping the second package structure PS2 180° in the normal direction Z of the electronic unit 1, and at this time, as shown in FIG. 2D and FIG. 2E, the second crack stopper layer 2 and the metal layer 6 will be turned from being disposed above the electronic unit 1 to being disposed below the electronic unit 1, and the first crack stopper layer 11 will be turned from being disposed below the semiconductor structure 12 to being disposed above the semiconductor structure 12.

In one embodiment of the present disclosure, as shown in FIG. 2E, the circuit structure 4 comprises a first part 4a and a second part 4b, and the second insulating layer 5 comprises a first part 5a and a second part 5b, wherein the first part 5a of the second insulating layer 5 is disposed between the first insulating layer 3 and the second part 5b of the second insulating layer 5, the first part 4a of the circuit structure 4 is electrically connected to the semiconductor structure 12 through the pad 13, and the second part 4b of the circuit structure 4 is electrically connected to the first part 4a of the circuit structure 4 through the opening 5al of the first part 5a of the second insulating layer 5.

In one embodiment of the present disclosure, as shown in FIG. 2E, a peeling layer C21 may be selectively disposed between the second carrier C2 and the second package structure PS2 after turning, and the peeling layer C21 may facilitate the subsequent step of separating the second carrier C2 and the second package structure PS2 after turning. In one embodiment of the present disclosure, before the step of disposing the second package structure PS2 after turning on the second carrier C2, a step of removing the first carrier C1 may be included.

In the present disclosure, the method for disposing the circuit structure 4 and the second insulating layer 5 and the method for removing the first carrier C1 may be as described above, and are not described here again. In the present disclosure, the method for patterning the first crack stopper layer 11 may be similar to or different from the method for patterning the first insulating layer 3, and suitable method may include lithography and etching, wherein the etching may include dry etching, wet etching or a combination thereof; but the present disclosure is not limited thereto. In the present disclosure, the opening 5al of the first part 5a of the second insulating layer 5 may be formed by patterning the first part 5a of the second insulating layer 5, and suitable method comprises laser process, lithography, etching or other suitable patterning method, wherein etching may comprise dry etching, wet etching or a combination thereof; but the present disclosure is not limited thereto. In the present disclosure, the materials of the second carrier C2, the circuit structure 4 and the second insulating layer 5 may be as described above, and are not described again here. In the present disclosure, the conductive material M may comprise tin, silver, copper, nickel, gold, an alloy thereof or a combination thereof; but the present disclosure is not limited thereto.

FIG. 3A is a cross-sectional schematic view of an electronic device according to one embodiment of the present disclosure. FIG. 3B and FIG. 3C respectively are enlarged views of FIG. 3A.

In one embodiment of the present disclosure, as shown in FIG. 3A, the electronic device may comprise: an electronic unit 1 comprising a semiconductor structure 12 and a first crack stopper layer 11 disposed on a first side 12s1 of the semiconductor structure 12; a second crack stopper layer 2 disposed on a second side 12s2 of the semiconductor structure 12, wherein the first side 12s1 is opposite to the second side 12s2; and a first insulating layer 3 surrounding the electronic unit 1. In the present disclosure, by the design of the first crack stopper layer 11 and the second crack stopper layer 2, the damage of the electronic unit 1 during the manufacturing process can be reduced, and the product yield of the electronic device can be improved. In the present disclosure, the Young's modulus of the first crack stopper layer 11 may be less than the Young's modulus of the second crack stopper layer 2 to improve the reliability of the electronic device.

In one embodiment of the present disclosure, as shown in FIG. 3A, the electronic unit 1 may comprise a pad 13, and the electronic unit 1 can input or output signal through the pad 13. In one embodiment of the present disclosure, as shown in FIG. 3A, the first crack stopper layer 11 may comprise an opening 111 to expose the pad 13; the second crack stopper layer 2 may comprise at least one opening 21 to expose a part of the electronic unit 1. In detail, along a direction perpendicular to the direction Z (for example, the X direction), the semiconductor structure 12 has a first width W1, and the opening 21 has a second width W2 (for example, the width of the bottom of the opening 21), wherein the sum of the second widths W2 of the openings 21 is less than or equal to the first width W1, and a ratio of the sum of the second widths W2 of the openings 21 to the first width W1 is greater than or equal to 0.5 and less than or equal to 1 to improve the heat dissipation effect of the electronic device; but the present disclosure is not limited thereto. In one embodiment of the present disclosure, as shown in FIG. 3A, the thickness T1 of the first crack stopper layer 11 may be greater than or equal to the thickness T2 of the second crack stopper layer 2. The thickness T1 of the first crack stopper layer 11 may be, for example, between 5 μm and 30 μm (5 μm≤T1≤30 μm); and the thickness T2 of the second crack stopper layer 2 may be, for example, between 0.5 μm and 10 μm (0.5 μm≤T2≤10 μm); but the present disclosure is not limited thereto. When the thicknesses of the first crack stopper layer 11 and the second crack stopper layer 2 meets the aforesaid limitations, the reliability of the electronic device may be improved. In one embodiment of the present disclosure, as shown in FIG. 3A, the first insulating layer 3 further surrounds the second crack stopper layer 2. In one embodiment of the present disclosure, as shown in FIG. 3A, the first insulating layer 3 may comprise a through via H1 penetrating the first insulating layer 3. More specifically, the through via H1 comprises a through via 31 and a through via 32, and the through via 31 and the through via 32 are connected to each other and penetrate the first insulating layer 3.

In one embodiment of the present disclosure, as shown in FIG. 3B, the side wall 11s1 of the first crack stopper layer 11 may be approximately parallel to the top view direction Z of the electronic unit 1; but the present disclosure is not limited thereto. In other embodiments, as shown in FIG. 3C, the side wall 11s1 of the first crack stopper layer 11 may not be parallel to the top view direction Z of the electronic unit 1. For example, an acute angle may be included between the side wall 11s1 of the first crack stopper layer 11 and the top view direction Z of the electronic unit 1, so that the contact area between the first insulating layer 3 and the electronic unit 1 may be increased to improve the reliability of the electronic device.

In one embodiment of the present disclosure, as shown in FIG. 3A, the electronic device may further comprise: a circuit structure 4 electrically connected to the semiconductor structure 12 through the pad 13 of the electronic unit 1. In one embodiment of the present disclosure, as shown in FIG. 3A, the electronic device may further comprise: a metal layer 6 disposed on the electronic unit 1, the second crack stopper layer 2 and the first insulating layer 3, wherein the metal layer 6 is electrically connected to the circuit structure 4. In detail, the metal layer 6 may comprise a first part 6a and a second part 6b separated from each other, wherein the first part 6a is disposed in the opening 21 of the second crack stopper layer 2 and contacts a part of the electronic unit 1, and the second part 6b is disposed in the through via 32 of the first insulating layer 3 and contacts and is electrically connected to the circuit structure 4. In one embodiment of the present disclosure, as shown in FIG. 3A, a projection area of the first part 6a of the metal layer 6 may be greater than or equal to a projection area of the electronic unit 1; but the present disclosure is not limited thereto. The first part 6a of the metal layer 6 may have the heat dissipation effect. Signals may be input into or output from the electronic unit 1 through the second part 6b of the metal layer 6 and the circuit structure 4. In one embodiment of the present disclosure, as shown in FIG. 3A, the metal layer 6 may comprise a first sub-metal layer 61 and a second sub-metal layer 62 disposed on the first sub-metal layer 61, wherein the first sub-metal layer 61 of the first part 6a may contact the electronic unit 1 through the opening 21 of the second crack stopper layer 2, and the first sub-metal layer 61 of the second part 6b may contact and be electrically connected to the circuit structure 4 through the through via 32 of the first insulating layer 3.

In one embodiment of the present disclosure, as shown in FIG. 3A, the electronic device may further comprise: a second insulating layer 5 disposed on one side of the circuit structure 4; and a third insulating layer 7 disposed on the first insulating layer 3 and surrounding the metal layer 6. In one embodiment of the present disclosure, as shown in FIG. 3A, the second insulating layer 5 is disposed adjacent to the first side 12s1 compared with the second side 12s2 of the semiconductor structure 12, and the third insulating layer 7 is disposed adjacent to the second side 12s2 compared with the first side 12s1 of the semiconductor structure 12. In one embodiment of the present disclosure, as shown in FIG. 3A, the electronic device may further comprise: a connecting unit 8 disposed on the metal layer 6 and electrically connected to the metal layer 6. More specifically, the connecting unit 8 may comprise a first part 8a and a second part 8b separated from each other, wherein the first part 8a of the connecting unit 8 is disposed on the first part 6a of the metal layer 6, and the second part 8b of the connecting unit 8 is disposed on the second part 6b of the metal layer 6. In one embodiment of the present disclosure, as shown in FIG. 3A, the surface of the connecting unit 8 is not coplanar with the surface of the third insulating layer 7; but the present disclosure is not limited thereto.

In the present disclosure, the materials and other features of the first crack stopper layer 11, the second crack stopper layer 2, the first insulating layer 3, the circuit structure 4, the second insulating layer 5, the metal layer 6, the third insulating layer 7 and the connecting unit 8 are as described above and are not described here again.

FIG. 4 is a cross-sectional schematic view of an electronic device according to one embodiment of the present disclosure. Herein, the electronic device of FIG. 4 is similar to that shown in FIG. 3A, except for the following differences.

In one embodiment of the present disclosure, as shown in FIG. 4, the electronic device may further comprise an insulating layer 9 disposed on the first insulating layer 3, wherein the insulating layer 9 is disposed between the first insulating layer 3 and the third insulating layer 7. In one embodiment of the present disclosure, as shown in FIG. 4, the insulating layer 9 may surround the electronic unit 1 and the second crack stopper layer 2.

In one embodiment of the present disclosure, as shown in FIG. 4, a part of the second crack stopper layer 2 protrudes from the electronic unit 1. More specifically, the second crack stopper layer 2 may comprise a protrusion portion 2a, and the protrusion portion 2a and the electronic unit 1 are not overlapped in the top view direction Z of the electronic unit 1. In one embodiment of the present disclosure, as shown in FIG. 4, the protrusion portion 2a of the second crack stopper layer 2 may contact the side wall 1s1 of the electronic unit 1. In one embodiment of the present disclosure, the protrusion portion 2a may have a structure such as an “L” shape or a mirrored “L” shape; but the present disclosure is not limited thereto. The protrusion portion 2a may increase the contact area between the second crack stopper layer 2 and the insulating layer 9 to improve the reliability of the electronic device.

In one embodiment of the present disclosure, as shown in FIG. 4, the first insulating layer 3 may comprise a through via 31, the insulating layer 9 may comprise a through via 91 and a through via 92, and the through via 31, the through via 91 and the through via 92 are connected each other to form a through via H2 which may penetrate through the first insulating layer 3 and the insulating layer 9.

In the present disclosure, the material of the insulating layer 9 may be as described above, and is not described again here.

FIG. 5 is a cross-sectional schematic view of an electronic device according to one embodiment of the present disclosure. Herein, the electronic device of FIG. 5 is similar to that shown in FIG. 3A, except for the following differences.

In the present disclosure, the method for manufacturing the electronic device shown in FIG. 5 is similar to that shown in FIG. 2A to FIG. 2E, and is not described again here.

In one embodiment of the present disclosure, as shown in FIG. 5, a part of the second crack stopper layer 2 protrudes from the electronic unit 1. More specifically, the second crack stopper layer 2 may comprise a protrusion portion 2a, and the protrusion portion 2a and the electronic unit 1 is not overlapped in the top view direction Z of the electronic unit 1. In one embodiment of the present disclosure, as shown in FIG. 5, the protrusion portion 2a of the second crack stopper layer 2 may contact the side wall 1s1 of the electronic unit 1. In one embodiment of the present disclosure, the protrusion portion 2a may have a structure such as an “L” shape or a mirrored “L” shape; but the present disclosure is not limited thereto. The protrusion portion 2a may increase the contact area between the second crack stopper layer 2 and the first insulating layer 3 to improve the reliability of the electronic device. In addition, the circuit structure 4 and the second insulating layer 5 may be formed separately and then joined to the electronic unit 1 through another conductive material M′, wherein at least one sub-layer of the second insulating layer 5 (for example, the first part 5a or the second part 5b of the second insulating layer 5) comprise a through via (for example, the opening 5al of the first part 5a or the opening 5b1 of the second part 5b), and the through via may penetrate through sub-layers (for example, through silicon via or through glass via) to improve the flexibility of the electronic device. In addition, as shown in FIG. 5, the electronic device may comprise another circuit structure 4′ disposed in the opening 111 of the first crack stopper layer 11, and the circuit structure 4′ may be electrically connected to the electronic unit 1 through the pad 13. In one embodiment of the present disclosure, the electronic device may comprise another insulating layer IL3 disposed between the electronic unit 1 and the circuit structure 4 and the conductive material M′ may be disposed in the through via IL3h of another insulating layer IL3. In the present disclosure, the material of the circuit structure 4′ is similar to the material of the circuit structure 4, and is not described here again. The conductive material M′ may comprise tin, silver, copper, nickel, gold, an alloy thereof or a combination thereof; but the present disclosure is not limited thereto. The material of the insulating layer IL3 may comprise silicon nitride, silicon oxide, silicon oxynitride, silicon carbonitride or a combination thereof; but the present disclosure is not limited thereto.

In one embodiment of the present disclosure, the step of patterning the second crack stopper layer 2 and the first insulating layer 3 may be omitted, so the second crack stopper layer 2 may not comprise the opening 21 shown in FIG. 3A, and the first insulating layer may not comprise the through via H1 shown in FIG. 3A. In one embodiment of the present disclosure, as shown in FIG. 5, the circuit structure 4 may be disposed on the first side 12s1 of the semiconductor structure 12, and electrically connected to the semiconductor structure 12 through the pad 13 of the electronic unit 1. More specifically, the circuit structure 4 comprises a first part 4a and a second part 4b, and the second insulating layer 5 comprises a first part 5a and a second part 5b, wherein the first part 5a of the second insulating layer 5 is disposed between the first insulating layer 3 and the second part 5b of the second insulating layer 5, and the first part 4a of the circuit structure 4 is electrically connected to the semiconductor structure 12 through another conductive material M′, another circuit structure 4′ and the pad 13. The second part 4b of the circuit structure 4 is electrically connected to the first part 4a of the circuit structure 4 disposed in the opening 5al of the first part 5a of the second insulating layer 5. In one embodiment of the present disclosure, as shown in FIG. 5, the metal layer 6 is disposed on the second crack stopper layer 2, and is electrically isolated from the circuit structure 4. The metal layer 6 may have a comb structure which can improve the heat dissipation effect of the electronic unit.

In one embodiment of the present disclosure, as shown in FIG. 5, the electronic device may further comprise a conductive material M which may be electrically connected to the semiconductor structure 12 through the circuit structure 4, the conductive material M′, the circuit structure 4′ and the pad 13 to transmit a signal from the electronic unit 1 to outside or transmit a signal from outside to the electronic unit 1. In the present disclosure, the conductive material M may comprise tin, silver, copper, nickel, gold, an alloy thereof or a combination thereof; but the present disclosure is not limited thereto.

FIG. 6 is a cross-sectional schematic view of an electronic device according to one embodiment of the present disclosure. Herein, the electronic device of FIG. 6 is similar to that shown in FIG. 3A, except for the following differences.

In one embodiment of the present disclosure, as shown in FIG. 6, a part of the second crack stopper layer 2 protrudes from the electronic unit 1. More specifically, the second crack stopper layer 2 may comprise a protrusion portion 2a, and the protrusion portion 2a and the electronic unit 1 are not overlapped in the top view direction Z of the electronic unit 1. In one embodiment of the present disclosure, as shown in FIG. 6, the protrusion portion 2a of the second crack stopper layer 2 may contact the side wall 1s1 of the electronic unit 1. In one embodiment of the present disclosure, the protrusion portion 2a may have the structure of “1” shape; but the present disclosure is not limited thereto. The protrusion portion 2a may increase the contact area between the second crack stopper layer 2 and the first insulating layer 3 to improve the reliability of the electronic device.

In one embodiment of the present disclosure, as shown in FIG. 6, the electronic unit 1 may have a concave corner portion 1a, and the second crack stopper layer 2 may cover the concave corner portion 1a. The “concave corner portion” refers to, for example, the uneven surface of the second side 12s2 of the semiconductor structure 12. The concave corner portion 1a may increase the contact area between the second crack stopper layer 2 and the electronic unit 1 to improve the reliability of the electronic device.

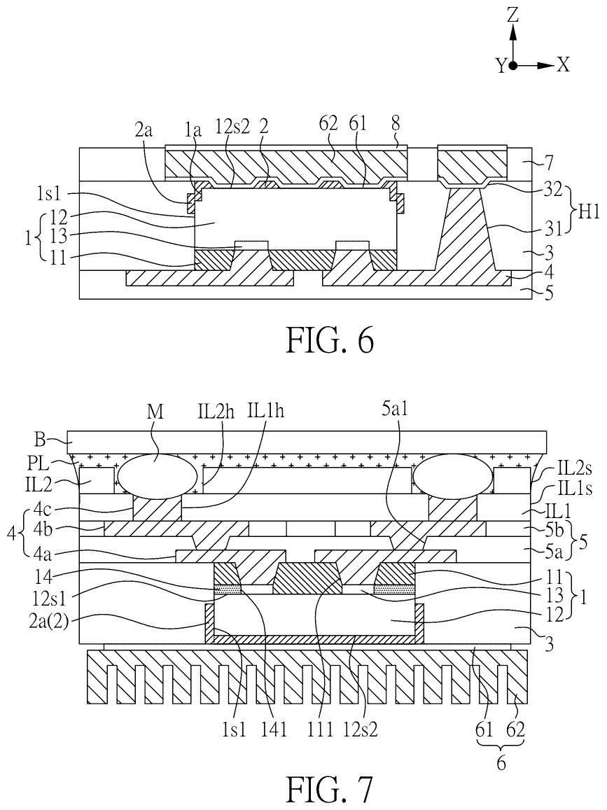

FIG. 7 is a cross-sectional schematic view of an electronic device according to one embodiment of the present disclosure. Herein, the electronic device of FIG. 7 is similar to that shown in FIG. 3A, except for the following differences.

In one embodiment of the present disclosure, as shown in FIG. 7, the electronic unit 1 may comprise a passivation layer 14 disposed between the first crack stopper layer 11 and the semiconductor structure 12, wherein the passivation layer 14 has an opening 141, the pad 13 is disposed in the opening 141, and the first crack stopper layer 11 exposes the pad 13. The second crack stopper layer 2 may comprise a protrusion portion 2a contacting the side wall 1s1 of the electronic unit 1, wherein the protrusion portion 2a may have a structure of, for example, a “1” shape; but the present disclosure is not limited thereto. The first insulating layer 3 surrounds the electronic unit 1 and the second crack stopper layer 2. In the present disclosure, the opening 141 of the passivation layer 14 may be formed through mechanical drilling, laser drilling, lithography or a combination thereof; but the present disclosure is not limited thereto. In the present disclosure, the material of the passivation layer 14 may comprise silicon nitride, silicon oxide, silicon oxynitride, silicon carbonitride or a combination thereof; but the present disclosure is not limited thereto.

In one embodiment of the present disclosure, as shown in FIG. 7, the circuit structure 4 comprises a first part 4a and a second part 4b, and the second insulating layer 5 comprises a first part 5a and a second part 5b, wherein the first part 5a of the second insulating layer 5 is disposed between the first insulating layer 3 and the second part 5b of the second insulating layer 5, the first part 4a of the circuit structure 4 is electrically connected to the semiconductor structure 12 through the pad 13, and the second part 4b of the circuit structure 4 is electrically connected to the first part 4a of the circuit structure 4 through the opening 5al of the first part 5a of the second insulating layer 5.

In one embodiment of the present disclosure, as shown in FIG. 7, the electronic device further comprises another insulating layer IL1 disposed on the second insulating layer 5, and the insulating layer IL1 has a through via IL1h. The circuit structure 4 further comprises a third part 4c disposed in the through via IL1h of the insulating layer IL1, wherein the second part 4b of the circuit structure 4 is disposed between the first part 4a and the third part 4c, and the third part 4c of the circuit structure 4 is electrically connected to the second part 4b. In the present disclosure, the through via IL1h of the insulating layer IL1 may be formed through mechanical drilling, laser drilling, lithography or a combination thereof; but the present disclosure is not limited thereto. In the present disclosure, the material o the insulating layer IL1 may comprise silicon nitride, silicon oxide, silicon oxynitride, silicon carbonitride or a combination thereof; but the present disclosure is not limited thereto.

In one embodiment of the present disclosure, the first crack stopper layer 11 may comprise a first filler, the second insulating layer 5 may comprise a second filler, and the insulating layer IL1 may comprise a third filler. The size of the first filler is less than the size of the second filler, and the size of the second filler is less than the size of the third filler. The “size of the filler” refers to, for example, the particle distribution (D50) of the filler or the average particle size of the filler. In the present disclosure, the materials of the first filler, the second filler and the third filler may be the same or different, wherein the materials of the first filler, the second filler and the third filler may respectively comprise silicon dioxide, titanium oxide, aluminum oxide, silicon carbide, graphene, other heat dissipation material or a combination thereof; but the present disclosure is not limited thereto.

In one embodiment of the present disclosure, as shown in FIG. 7, the metal layer 6 is disposed on the second side 12s2 of the semiconductor structure 12, wherein the second crack stopper layer 2 is disposed between the semiconductor structure 12 and the metal layer 6. In detail, the metal layer 6 may comprise a first sub-metal layer 61 and a second sub-metal layer 62, and the first sub-metal layer 61 is disposed between the second sub-metal layer 62 and the second crack stopper layer 2, wherein the first sub-metal layer 61 may contact and be electrically connected to the second crack stopper layer 2, and the second sub-metal layer 62 of the metal layer 6 may have a comb structure to improve the heat dissipation effect of the electronic unit.

In one embodiment of the present disclosure, as shown in FIG. 7, the electronic unit 1 may be electrically connected to a circuit board B through a conductive material M to drive or control the electronic unit 1. More specifically, the electronic unit 1 may be electrically connected to the circuit structure 4 through the pad 13, and electrically connected to the conductive material M through the circuit structure 4, thereby transmitting a signal from the circuit board B to the electronic unit 1 or transmitting a signal from the electronic unit 1 to the circuit board B. In one embodiment of the present disclosure, as shown in FIG. 7, the electronic device further comprise another insulating layer IL2 disposed on another insulating layer IL1. The insulating layer IL2 has a through via IL2h, and the conductive material M may be disposed in the through via IL2h. In the present disclosure, the circuit board B may comprise a rigid circuit board or a flexible circuit board, such as a printed circuit board (PCB) or a flexible printed circuit (FPC); but the present disclosure is not limited thereto. In the present disclosure, the conductive material M may comprise tin, silver, copper, nickel, gold, an alloy thereof or a combination thereof; but the present disclosure is not limited thereto. In the present disclosure, the through via IL2h of the insulating layer IL2 may be formed by mechanical drilling, laser drilling, lithography or a combination thereof; but the present disclosure is not limited thereto. In the present disclosure, the material of the insulating layer IL2 may comprise silicon nitride, silicon oxide, silicon oxynitride, silicon carbonitride or a combination thereof; but the present disclosure is not limited thereto.

In one embodiment of the present disclosure, as shown in FIG. 7, the electronic device may comprise a protection layer PL disposed between the circuit board B and the circuit structure 4. More specifically, the protection layer PL may surround or cover the conductive material M, the insulating layer IL1 and/or the insulating layer IL2. In one embodiment of the present disclosure, as shown in FIG. 7, the protection layer PL may contact the side wall IL1s of the insulating layer IL1 and/or the side wall IL2s of the insulating layer IL2. The protection layer PL may be used to block the entry of outside air or moisture to improve the reliability of the electronic device. In the present disclosure, the material of the protection layer PL may comprise glass glue, optical glue, silicone glue, hot melt glue, AB glue, light-curing glue, polymer glue, resin or a combination thereof; but the present disclosure is not limited thereto.

In the present disclosure, the disposition of the first crack stopper layer 11 and the second crack stopper layer 2 may be used to protect the components in the electronic unit 1, thereby reducing the damage to the electronic unit 1 in the subsequent processing steps to improve the production yield of the electronic device.

The above specific embodiments should be construed as illustrative only and not in any way limiting of the remainder of the present disclosure.

Although the present disclosure has been explained in relation to its embodiment, it is to be understood that many other possible modifications and variations can be made without departing from the spirit and scope of the disclosure as hereinafter claimed.

1. An electronic device, comprising:
an electronic unit comprising a semiconductor structure and a first crack stopper layer disposed on a first side of the semiconductor structure;
a second crack stopper layer disposed on a second side of the semiconductor structure, wherein the first side is opposite to the second side; and
a first insulating layer surrounding the electronic unit,
wherein a Young's modulus of the first crack stopper layer is less than a Young's modulus of the second crack stopper layer.

2. The electronic device of claim 1, wherein a thickness of the first crack stopper layer is greater than or equal to a thickness of the second crack stopper layer.

3. The electronic device of claim 1, wherein the first insulating layer surrounds the second crack stopper layer.

4. The electronic device of claim 1, further comprising: a circuit structure electrically connected to the semiconductor structure through a pad of the electronic unit, wherein the pad is exposed from the first crack stopper layer.

5. The electronic device of claim 4, further comprising: a metal layer disposed on the electronic unit, the second crack stopper layer and the first insulating layer, wherein the metal layer is electrically connected to the circuit structure.

6. The electronic device of claim 5, further comprising:
a second insulating layer disposed on a side of the circuit structure; and
a third insulating layer disposed on the first insulating layer and surrounding the metal layer.

7. The electronic device of claim 5, further comprising: a connecting unit disposed on the metal layer and electrically connected to the metal layer.

8. The electronic device of claim 1, wherein the second crack stopper layer comprises an opening, and a part of the electronic unit is exposed from the opening.

9. The electronic device of claim 1, wherein a part of the second crack stopper layer protrudes from the electronic unit.

10. The electronic device of claim 1, wherein the first insulating layer comprises a through via penetrating through the first insulating layer.

11. A method for manufacturing an electronic device, comprising the following steps:
providing an electronic unit and a second crack stopper layer on the first carrier, wherein the electronic unit comprises a semiconductor structure and a first crack stopper layer disposed on a first side of the semiconductor structure, the second crack stopper layer is disposed on a second side of the semiconductor structure, and the first side is opposite to the second side;
disposing a first insulating layer on the first carrier, the electronic unit and the second crack stopper layer so that the first insulating layer surrounds the electronic unit to form a first package structure;
turning over the first package structure and disposing the first package structure after turning on a second carrier;
patterning the first insulating layer to form a through via;
disposing a circuit structure and a second insulating layer on the first package structure to form a second package structure;
turning over the second package structure and disposing the second package structure after turning on a third carrier;
grinding the first insulating layer and a part of the second crack stopper layer to expose a part of the electronic unit;
disposing a metal layer on the electronic unit and the first insulating layer; and
disposing a third insulating layer on the first insulating layer, wherein the third insulating layer surrounds the metal layer,
wherein a Young's modulus of the first crack stopper layer is less than a Young's modulus of the second crack stopper layer.

12. The method of claim 11, further comprising a step of: disposing a connecting unit on the metal layer before the step of disposing the third insulating layer on the first insulating layer.

13. The method of claim 11, wherein a part of the second crack stopper layer protrudes from the electronic unit.

14. The method of claim 11, wherein the circuit structure is electrically connected to the semiconductor structure through a pad of the electronic unit.

15. The method of claim 14, wherein the pad of the electronic device is exposed from the first crack stopper layer.

16. A method for manufacturing an electronic device, comprising the following steps:
providing an electronic unit on a first carrier, wherein the electronic unit comprises a semiconductor structure and a first crack stopper layer disposed on a first side of the semiconductor structure;
disposing a first insulating layer on the first carrier so that the first insulating layer surrounds the electronic unit;
disposing a second crack stopper layer on the electronic unit and the first insulating layer to form a first package structure, wherein the second crack stopper layer is disposed on a second side of the semiconductor structure, and the first side is opposite to the second side;
disposing a metal layer and a third insulating layer on the first package structure;
grinding a part of the metal layer and the third insulating layer to expose a part of the metal layer to form a second package structure;
turning over the second package structure and disposing the second package structure after turning on a second carrier;
disposing a circuit structure and a second insulating layer on the second package structure after turning; and
disposing a conductive material on the circuit structure,
wherein a Young's modulus of the first crack stopper layer is less than a Young's modulus of the second crack stopper layer.

17. The method of claim 16, further comprising a step of: patterning the first crack stopper layer to form an opening before the step of disposing the circuit structure and the second insulating layer on the second package structure after turning.

18. The method of claim 17, wherein the electronic unit comprises a pad electrically connected to the semiconductor structure, and the pad is exposed from the opening of the first crack stopper layer.

19. The method of claim 16, wherein a part of the second crack stopper layer protrudes from the electronic unit.

20. The method of claim 16, wherein the circuit structure is electrically connected to the semiconductor structure through a pad of the electronic unit.
